(19) United States
(12) Patent Application Publication
(10) Pub. No.: US 2008/0166851 A1
(43) Pub. Date: Jul. 10, 2008

(54) METAL-INSULATOR-METAL (MIM) CAPACITOR AND METHOD FOR FABRICATING THE SAME

(76) Inventors: Uk-Sun HONG, Sungnam-city (KR); Sang-Rok Hah, Seoul (KR); Hong-Seong Son, Suwon-city (KR)

Correspondence Address: Frank Chau, Esq.;F. CHAU & ASSOCIATES, LLP, Suite 501, 1900 Hempstead Turnpike, East Meadow, NY, 11554, US

(21) Appl. No.: 12/030,476

(22) Filed: Feb. 13, 2008

(30) Foreign Application Priority Data
Jun. 17, 2002 (KR) 2002-33733

(51) Int. Cl. H01L 21/02

(52) U.S. Cl. 438/393; 257/E21.021

(57) ABSTRACT

The present invention discloses a metal-insulator-metal (MIM) capacitor and a method for fabricating the MIM capacitor, comprising forming a bottom insulation layer, a capacitor electrode material layer, and a hard mask material layer on a semiconductor substrate having a metal wire thereon; forming a hard mask by etching the hard mask material layer using a photosensitive mask; forming a capacitor electrode by etching the capacitor electrode material layer using the hard mask as an etching mask; and forming a top insulation layer on an entire surface of the semiconductor.

### CROSS-REFERENCE TO RELATED APPLICATION

This application is a divisional of U.S. patent application Ser. No. 10/447,114, filed on May 28, 2003, which in turn claims priority under 35 U.S.C. § 119 to Korean Patent Application No. 10-2002-33733 filed on Jun. 17, 2002, the disclosures of which are each all incorporated herein by reference in their entirety.

### BACKGROUND OF INVENTION

1. Field of the Invention

The present invention relates to logic analog semiconductor devices, more particularly to a metal-insulator-metal (MIM) capacitor compatible with a dual damascene process and a method for fabricating the same.

2. Description of Related Art

Generally, electrodes of a MIM capacitor used in logic analog devices are formed of the same material as a wire, for example, a metal such as aluminum Al, copper, or a barrier metal such as tantalum nitride TaN. A MIM capacitor with an electrode using a barrier metal is more widely used in comparison with a MIM capacitor using wire metal due to the simple fabrication process and characteristic stability of the electrode material.

FIGS. 1A to 1D are cross-sectional views showing a method for fabricating a semiconductor device with a MIM capacitor in accordance with the conventional art.

As shown in FIG. 1A, there is provided a semiconductor substrate 100 including a copper wire 110 formed thereon by a damascene process. A bottom nitride layer 120 is formed to a thickness of 700 Å on the entire surface of the semiconductor substrate 100 including the copper wire 110. Then, a barrier metal layer 130 for a capacitor electrode such as a tantalum nitride TaN layer is formed on the bottom nitride layer 120 to a thickness of 700 Å. A photosensitive film 190 is formed on the TaN layer 130 to a thickness of 8000 Å and then patterned, so that the photosensitive film 190 remains on a portion of the TaN layer 130 where the capacitor electrode is to be formed.

As shown in FIG. 1B, an exposed part of the TaN layer 130 is etched by using the photosensitive film 190 shown in FIG. 1A, as an etching mask, thereby forming a capacitor electrode 135. As shown in FIG. 1C, the photosensitive film 190 is removed and a top nitride layer 140 is formed over the entire surface of the semiconductor substrate to a thickness of 350 Å.

As shown in FIG. 1D, an inter-layer insulation film 150 is formed on the top nitride layer 140. Next, the inter-layer insulation film 150, the top nitride layer 140 and the bottom nitride layer 120 are etched to form via holes 161 and 165 exposing the copper wire 110 and the capacitor electrode 135, respectively. Next, a metal wire (not shown) is formed to fill the via holes 161 and 165 by a known damascene process.

The conventional method for fabricating the semiconductor device with the MIM capacitor has the following problems:

First, when the TaN layer 130 is etched using the photosensitive film 190 as an etching mask to form the capacitor electrode 135, a large amount of metal polymer is produced because the photosensitive film 190 is thick, the thickness being as great as 8000 Å. Since the metal polymer is not entirely removed during a HF cleaning process performed after forming the capacitor electrode 135, the remaining metal polymer causes problems during a subsequent pattern forming process. Accordingly, a dry etching process should be performed to remove the metal polymer entirely. However, during the dry etching process, the surface of the capacitor electrode 135 of the TaN layer is etch-damaged.

Second, since the inter-layer insulation film 150 is formed on the damaged surface of the capacitor electrode 135, the top nitride layer 140 or the inter-layer insulation film 150 is lifted.

Lastly, because the top and bottom nitride layers 120 and 140 are formed over the copper wire 110 and only the top nitride layer 140 is formed over the capacitor electrode 135, the total thickness of a silicon nitride SiN layer formed over the copper wire 110 is different from that formed over the capacitor electrode 135. When forming the via holes 161 and 165 on the copper wire 110 and the capacitor electrode 135, if the nitride layer is over-etched, the upper surface of the capacitor electrode is etch-damaged and electrical characteristics of the capacitor are changed. On the other hand, if the nitride layer is under-etched, the copper wire 110 is not exposed, causing an opening failure. Further, it is nearly impossible to adapt a dual damascene process in a semiconductor device with a MIM capacitor due to the thickness difference between the nitride layers over the copper wire 110 and the capacitor electrode 135. Therefore, a need exists for a method for fabricating a MIM capacitor capable of preventing opening fail of a metal wire and characteristic change of the capacitor.

### SUMMARY OF THE INVENTION

An embodiment of the present invention comprises a method for fabricating a MIM capacitor capable of preventing metal polymer formation and preventing a surface of a capacitor electrode from being etch-damaged by using a hard mask as an etching mask for the capacitor electrode.

In another embodiment of the present invention a method for fabricating a MIM capacitor capable of preventing layers formed over a capacitor electrode from being lifted, is provided.

In accordance with an embodiment of the present invention, there is provided a MIM capacitor, comprising a semiconductor substrate having a metal wire thereon, a bottom insulation layer formed on the semiconductor substrate, a capacitor electrode formed on the bottom insulation layer, a hard mask formed on the capacitor electrode, and a top insulation layer formed on the entire surface of the semiconductor substrate.

In accordance with another embodiment of the present invention, there is provided a method of fabricating a MIM capacitor, comprising sequentially forming a bottom insulation layer, a capacitor electrode material layer, and a hard mask material layer on a semiconductor substrate having a metal wire thereon, forming a hard mask by etching the hard mask material layer using a photomask, forming a capacitor electrode by etching the capacitor electrode material layer using the hard mask as an etching mask, and forming a top insulation layer on the entire surface of the semiconductor substrate.

The bottom and top insulation layers and the hard mask are comprised of a nitride layer. For a thickness difference between the total thickness of the bottom and top insulation layers over the metal wire, and the total thickness of the top insulation layer and the hard mask over the capacitor electrode, to be in a range of 0 to about 200 Å, the capacitor electrode material layer is etched under a condition that etching selectivity of the hard mask to the capacitor electrode material layer is in a range of about 5:1 to about 10:1.

In accordance with another embodiment of the present invention, there is provided a method of fabricating a semiconductor device including a MIM capacitor, comprising forming a bottom insulation layer and a capacitor electrode material layer on a semiconductor substrate having a first metal wire thereon, forming a hard mask on the capacitor electrode material layer, forming a capacitor electrode by etching the capacitor electrode material layer using the hard mask as an etching mask, forming a top insulation layer on the entire surface of the semiconductor substrate, forming an inter-layer insulation film on the entire surface of the semiconductor substrate, and forming via holes exposing the first metal wire and the capacitor electrode, respectively by etching the inter-layer insulation film, the top and bottom insulation layers, and the hard mask.

The method for fabricating the semiconductor device further comprises forming a second metal wire in the via holes using a dual damascene process, after forming the via holes.

### BRIEF DESCRIPTION OF THE DRAWINGS

These and other features and advantages of the present invention will be readily apparent to those of ordinary skill in the art upon review of the detailed description that follows when taken in conjunction with the accompanying drawings, in which like reference numerals denote like parts, and in which:

FIGS. 1A to 1D are cross-sectional views showing a method for fabricating a semiconductor device including a MIM capacitor in accordance with conventional art.

FIGS. 2A to 2E are cross-sectional views showing a method of fabricating a semiconductor device including a MIM capacitor in accordance with an embodiment of the present invention.

FIG. 3A is a graph showing unit capacitance distribution of the conventional MIM capacitor and the MIM capacitor in accordance with an embodiment of the present invention.

FIG. 3B is a graph showing leakage current distribution of the conventional MIM capacitor and the MIM capacitor in accordance with an embodiment of the present invention.

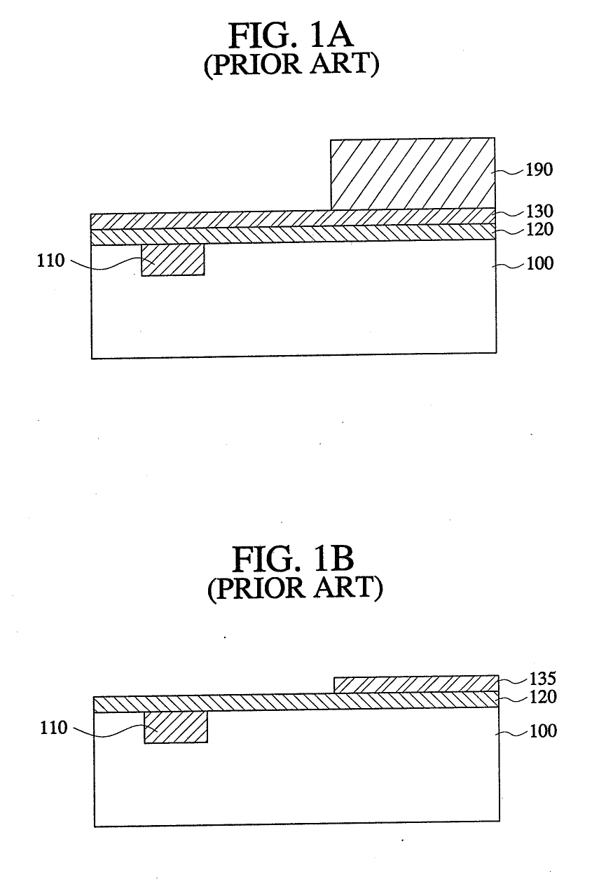

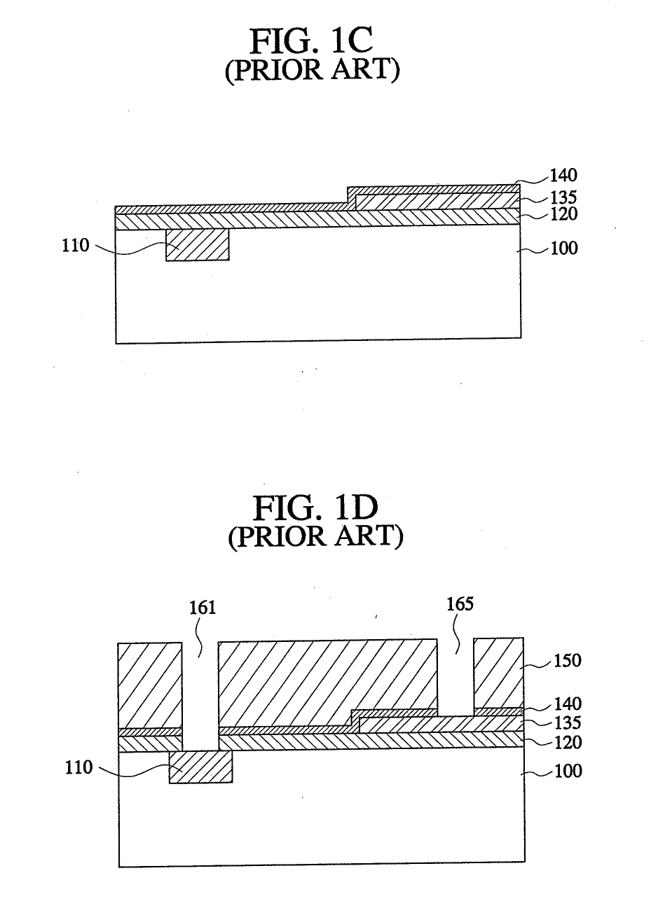

### DETAILED DESCRIPTION OF PREFERRED EMBODIMENTS

Reference will now be made in detail to preferred embodiments of the present invention, an example of which is illustrated in the accompanying drawings.

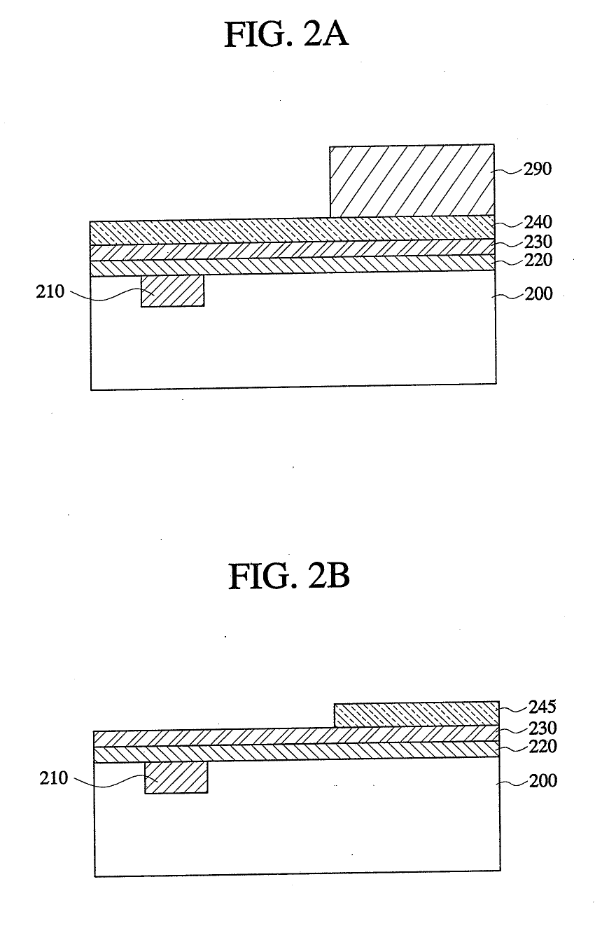

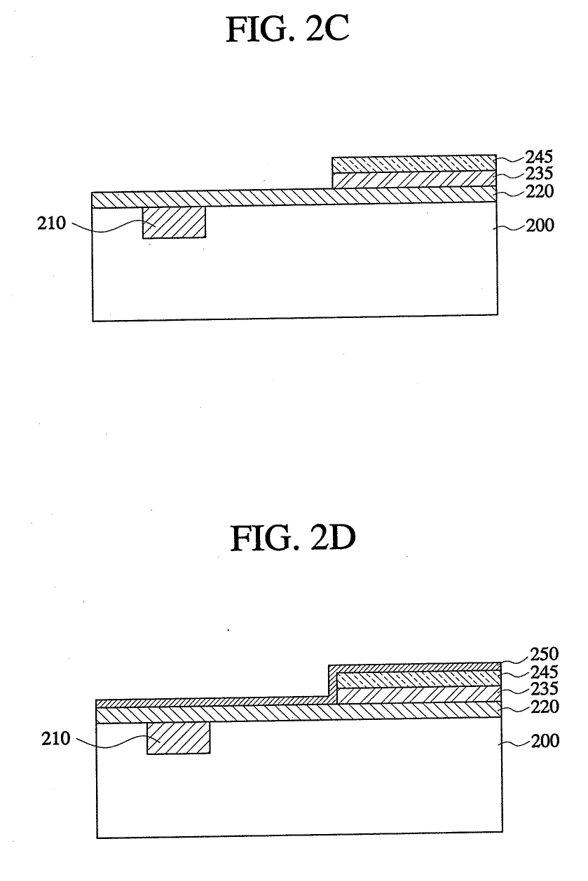

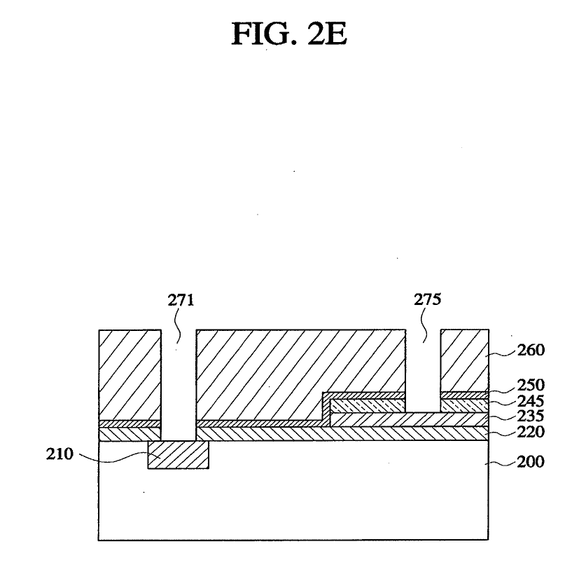

FIGS. 2A to 2E are cross-sectional views for showing a method for fabricating a semiconductor device including a MIM capacitor. First, as shown in FIG. 2A, a semiconductor substrate 100 including a copper wire 210 formed by a damascene process thereon is provided. A bottom nitride layer 220 which is used as an insulation film for an etch stopper is formed on the entire surface of the semiconductor substrate including the copper wire 210 to a thickness of about 850 Å. A barrier metal layer 230 for a capacitor electrode is formed on the bottom nitride layer 220 to a thickness of about 700 Å. The barrier metal layer 230 is formed of TaN. A nitride layer 240 for a hard mask is formed on the barrier metal layer 230 to a thickness of about 1000 Å. Then, a photosensitive film 290 is formed on the nitride layer 240 to a thickness greater than about 8000 Å and patterned, thereby remaining at a portion of the nitride layer 240 where the capacitor electrode is to be formed.

As shown in FIG. 2B, an exposed portion of the nitride layer 240 of FIG. 2A is etched by using the photosensitive film 290 of FIG. 2A as an etching mask, then the photosensitive film 290 is removed, thereby forming a hard mask 245. As shown in FIG. 2C, the barrier metal layer 230 of FIG. 2B is etched using the hard mask 245 as an etching mask, thereby forming a capacitor electrode 235 of TaN. The barrier metal layer 230 is etched under a condition that etching selectivity of the barrier metal layer 230 of TaN to the hard mask 245 of the nitride layer is in a range of about 5:1 to about 10:1. Accordingly, a portion of the nitride layer for the hard mask 245 is etched during etching the TaN layer for the barrier metal layer 230 to form the capacitor electrode 235. Thus, the thickness of the nitride layers on the copper wire 210 and the thickness of the nitride layers on the capacitor electrode 235 become almost the same.

In accordance with an embodiment of the present invention, the thickness difference between the nitride layer 220 formed on the copper wire 210 and the nitride layer for the hard mask 245 formed on the capacitor electrode 235 is adjusted to be in a range of 0 to about 200 Å. For example, when the etching process is carried out by using the TaN layer having a thickness of about 1000 Å as a target, taking into consideration a certain amount of over-etching, the nitride layer for the hard mask 245 and the bottom nitride layer 220 may have thicknesses of about 800 Å and about 700 Å, respectively.

In accordance with an embodiment of the present invention, the nitride layer 245 for the hard mask is etched using the photosensitive film 290 without exposing the barrier metal layer 230 of TaN, then the photosensitive film 290 is removed before etching the barrier metal layer 230 of TaN. Accordingly, the thickness of the photosensitive film 290 does not affect the processes for fabricating the capacitor.

That is, the metal polymer formation is prevented because the TaN layer is not exposed during etching the nitride layer 240 for the hard mask. Accordingly, the dry etching process to remove the metal polymer is not necessary and therefore etching damage of the surface of the capacitor electrode is not caused. Further, characteristic changes of the capacitor electrode may be prevented.

Next, as shown in FIG. 2D, a top nitride layer 250 is formed on the entire surface of the semiconductor substrate to a thickness of about 350 Å. The difference between total thickness of the nitride layers 220 and 250 formed over the copper wire 210 and total thickness of the nitride layers 245 and 250 formed over the capacitor electrode 235 is maintained in the range of 0 to about 200 Å.

If the capacitor electrode 235 and the top nitride layer 250 are used as a bottom plate and a dielectric layer of a MIM capacitor, respectively, a top plate of the MIM capacitor which is comprised of a barrier metal layer, for example TaN is formed on the top nitride layer 250. At this time, the thickness of the top nitride layer is determined considering a characteristic of the MIM capacitor such as capacitance.

As shown in FIG. 2E, an inter-layer insulation film 260 is formed on the entire surface of the semiconductor substrate 200 and then patterned to form via holes 271 and 275 that expose the copper wire 210 and the capacitor electrode 235, respectively. Next, a metal wire (not shown) is formed in the via holes 271 and 275 by a known damascene process, for example dual damascene process.

In accordance with the above embodiment of the present invention, there is no etching damage in the surface of the capacitor electrode or any lifting of the top nitride layer 250 or the inter-layer insulation film 260. The total thickness of the nitride layers formed over the copper wire 210 and the capacitor electrode 235 are almost the same, thereby forming the via holes without opening fail and adapting a dual damascene process to the metal wire process.

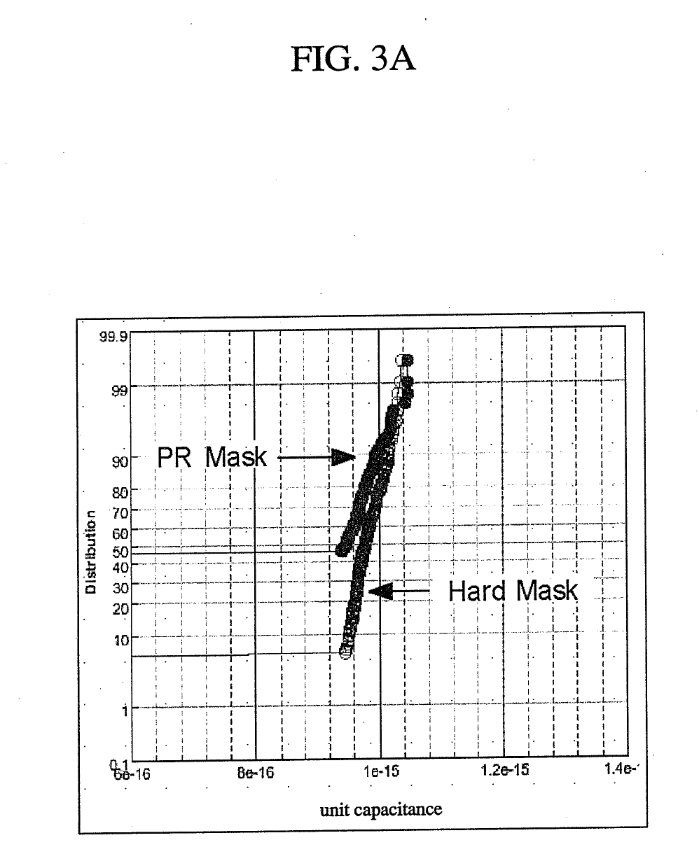

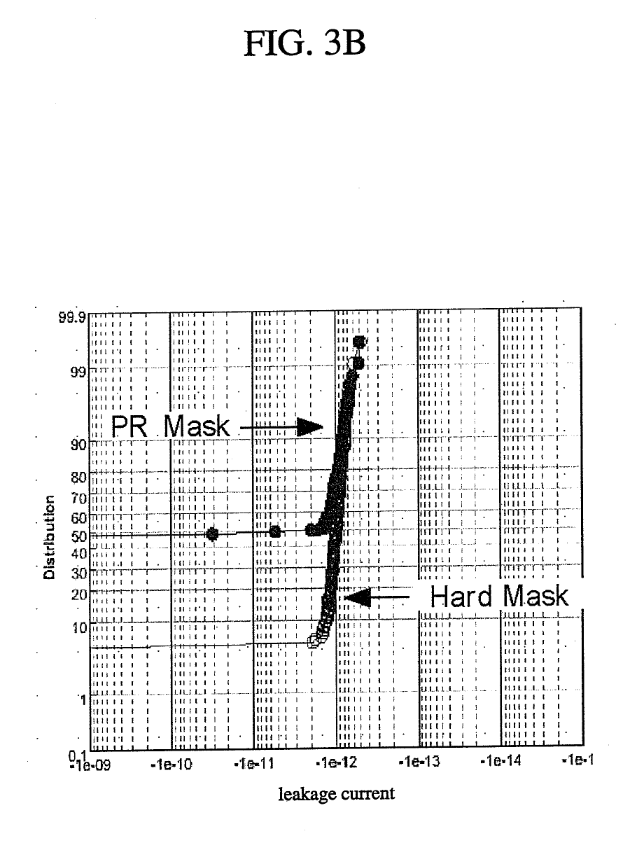

FIGS. 3A and 3B are graphs showing unit capacitance distribution and leakage current characteristic, respectively, wherein the graphs designated by the PR mask are related to the conventional MIM capacitor and the graphs designated by the hard mask are related to the MIM capacitor in accordance with the present invention.

As shown in FIGS. 3A and 3B, it is found that capacitor fail and leakage current can be reduced in the MIM capacitor in accordance with the present invention, compared to the conventional MIM capacitor.

In accordance with an embodiment of the present invention, the barrier metal layer of TaN to be the capacitor electrode, is etched using the hard mask as an etching mask. Accordingly, metal polymer formation is prevented and layers formed on the capacitor electrode are not lifted.

Further, by adjusting the total thickness difference between the nitride layers formed over the copper wire and the capacitor electrode to be in a range of 0 to about 200 Å, opening fail of the copper wire and capacitor characteristic change may be prevented.

While the invention has been particularly shown and described with reference to preferred embodiments thereof, it will be understood by those skilled in the art that the foregoing and other changes in form and details may be made therein without departing from the spirit and scope of the invention.

What is claimed is:

1. A method of fabricating a MIM capacitor, comprising:
sequentially forming a bottom insulation layer, a capacitor electrode material layer and a hard mask material layer on a semiconductor substrate having a metal wire thereon;
forming a hard mask by etching the hard mask material layer using a photosensitive mask;
forming a capacitor electrode by etching the capacitor electrode material layer using the hard mask as an etching mask; and
forming a top insulation layer on an entire surface of the semiconductor substrate.

2. The method according to claim 1, wherein the top and bottom insulation layers and the hard mask are formed of a nitride layer.

3. The method according to claim 1, wherein a thickness difference between a total thickness of the top and bottom insulation layers formed over the metal wire, and a total thickness of the top insulation layer and the hard mask formed over the capacitor electrode is in a range of 0 to about 200 Å.

4. The method according to claim 1, wherein the capacitor electrode is formed of a barrier metal layer.

5. The method according to claim 1, wherein the photosensitive mask is formed to a thickness greater than about 8000 Å.

6. The method according to claim 1, wherein the capacitor electrode is formed under a condition that etching selectivity of the hard mask to the capacitor electrode material layer is in a range of about 5:1 to about 10:1.

7. A method of fabricating a semiconductor device including a MIM capacitor, comprising:
forming a bottom insulation layer and a capacitor electrode material layer on a semiconductor substrate having a first metal wire thereon;
forming a hard mask on the capacitor electrode material layer;
forming a capacitor electrode by etching the capacitor electrode material layer using the hard mask as an etching mask;
forming a top insulation layer on an entire surface of the semiconductor substrate;
forming an inter-layer insulation film on the entire surface of the semiconductor substrate; and
forming via holes to expose the first metal wire and the capacitor electrode, respectively by etching the inter-layer insulation film, the top and bottom insulation layers, and the hard mask.

8. The method according to claim 7, wherein the capacitor electrode is formed under a condition that etching selectivity of the hard mask to the capacitor electrode material layer is in a range of about 5:1 to about 10:1 so that a thickness difference between a total thickness of the top and bottom insulation layers over the first metal wire, and a total thickness of the bottom insulation layer and the hard mask over the capacitor electrode is in a range of 0 to about 200 Å.

9. The method according to claim 7, wherein further comprising:
forming a second metal wire in the via holes by a dual damascene process.
